(19) United States
(12) Patent Application Publication
(10) Pub. No.: US 2006/0263706 A1
(43) Pub. Date: Nov. 23, 2006

(54) Overlay vernier and method for manufacturing semiconductor device using the same

(75) Inventor: Dong Gyu Yim, Gyunggi-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Gyunggi-do (KR)

(21) Appl. No.: 11/321,131

(22) Filed: Dec. 28, 2005

(30) Foreign Application Priority Data
May 18, 2005 (KR) 2005-41819

(51) Int. Cl. G03F 9/00; G03C 5/00; G03C 1/00

(52) U.S. Cl. 430/22; 430/30; 430/296; 430/942; 430/270.1

(57) ABSTRACT

An overlay vernier comprises overlay vernier patterns having a layout identical to that of patterns disposed within a real cell. A lower overlay vernier pattern is formed within a scribe line region along with a lower layer pattern as a lower layer of the real cell, and an upper overlay vernier pattern is formed within the scribe line region along with an upper layer pattern as an upper layer of the real cell. The lower overlay vernier pattern and the upper overlay vernier pattern have the same layout as that of the lower layer pattern and the upper layer pattern, respectively. The upper layer pattern and the lower layer pattern disposed within the real cell can be accurately aligned using the degree of overlap between the upper overlay vernier pattern and the lower overlay vernier pattern.

### CROSS-REFERENCES TO RELATED APPLICATIONS

The present disclosure relates to subject matter contained in Korean Application No. 10-2005-41819, filed on May 18, 2005, which is herein expressly incorporated by reference its entirety.

### BACKGROUND OF THE INVENTION

The present invention relates to an overlay vernier for aligning upper and lower layers on a wafer, and a method for manufacturing a semiconductor device using the overlay vernier.

Generally, real patterns are formed on a wafer along with an overlay vernier for determining and correcting the alignment of layers formed in sequential steps (i.e., a layer formed in a previous step and a layer to be formed in a subsequent step) during manufacture of a semiconductor device in a stacked structure. Specifically, a lower overlay vernier pattern is formed along with a lower layer pattern of a real cell, and an upper overlay vernier pattern is formed along with an upper layer pattern of the real cell. Subsequently, the degree of overlap between the upper layer pattern and the lower layer pattern is determined using the upper overlay vernier pattern and the lower overlay vernier pattern. The overlay vernier patterns are commonly positioned within a scribe line that is used to cut the die, and have a relatively simple layout, e.g., box-, bar-, or hole-shaped layout, when compared to that of the patterns of the real cell.

There may be a difference between the layout of the overlay vernier patterns and the layout of the patterns of the real cell. This difference causes various problems. For example, information regarding the alignment between the upper and lower patterns of the real cell may not match information regarding the alignment between the upper and lower overlay vernier patterns during a lamination process, such as physical vapor deposition or a thermal process. More specifically, if the lateral slopes of the overlay vernier patterns are asymmetric, the thickness of a film formed at the sides of the overlay vernier patterns by lamination becomes non-uniform, leading to a mismatch between information regarding the alignment between the patterns in the real cell and information regarding the alignment of the overlay vernier. Although the information regarding the alignment of the overlay vernier is fed back to correct the mismatch, the real cell is inevitably misaligned. This misalignment problem is severe at the edges of the wafer where the lateral slopes of the overlay vernier patterns are relatively asymmetric.

As another example, when a scanner/stepper with a large aberration is used upon light exposure, information regarding the alignment of patterns in a real cell may not match information regarding the alignment of an overlay vernier. More specifically, since the lens used in a scanner/stepper generally has a certain amount of aberration, the locus of light incident on the real cell is different from that of light incident on the overlay vernier due to the aberration of the lens. Accordingly, even when an upper overlay vernier pattern exactly overlaps the lower overlay vernier pattern, a misalignment takes place between the upper layer pattern and lower layer pattern of the real cell.

### BRIEF SUMMARY OF THE INVENTION

The present invention relates to providing an overlay vernier. In one embodiment an overlay vernier is provided to prevent a mismatch between information regarding the alignment of the overlay vernier and information regarding the alignment of patterns in a real cell, so that the patterns in the real cell can be accurately aligned. One aspect of the present invention provides an overlay vernier comprising overlay vernier patterns having a layout identical to that of patterns disposed within a real cell. The overlay vernier patterns can be disposed within a scribe line. The overlay vernier patterns can be formed in such a manner as to have a tone different from that of the patterns of the real cell.

Another embodiment relates to providing a method for manufacturing a semiconductor device using the overlay vernier. A method for manufacturing a semiconductor device comprises (1) forming a lower layer pattern within a first region of a wafer as in a real cell region, and forming a lower overlay vernier pattern having the same layout as that of the lower layer pattern within a second region of the wafer as in a scribe line; and (2) forming an upper layer pattern within the first region and forming an upper overlay vernier pattern having the same layout as that of the upper layer pattern within the second region, so that the upper overlay vernier pattern overlaps the lower overlay vernier pattern to align the upper layer pattern and the lower layer pattern.

This method above may further comprise the step of creating data of an ideal degree of overlap between the upper overlay vernier pattern and the lower overlay vernier pattern.

The step of aligning the upper layer pattern and the lower layer pattern may include the sub-steps of: comparing the results of the overlap between the upper overlay vernier pattern and the lower overlay vernier pattern with the data to measure errors therebetween; and correcting the degree of overlap between the upper overlay vernier pattern and the lower overlay vernier pattern by the errors to align the upper layer pattern and the lower layer pattern.

The results of the overlap between the upper overlay vernier pattern and the lower overlay vernier pattern can be determined by a scanning electron microscopic image.

The sub-step of comparing the results of the overlap between the upper overlay vernier pattern and the lower overlay vernier pattern with the data to measure errors therebetween can be carried out with respect to an X-axis and a Y-axis perpendicular to each other.

The second region may include a scribe line. The lower overlay vernier pattern may be formed in such a manner as to have a tone different from that of the lower layer pattern.

According to anther embodiment of the present invention, a method for manufacturing a semiconductor device comprises forming a lower layer pattern within a real cell region of a wafer; and forming an upper layer pattern within the real cell region so that the upper layer pattern directly overlaps the lower layer pattern to align the two layer patterns.

The method of the present invention may further comprise the step of creating data of an ideal degree of overlap between the upper layer pattern and the lower layer pattern.

The step of aligning the upper layer pattern and the lower layer pattern may include the sub-steps of: comparing the results of the overlap between the upper layer pattern and the lower layer pattern with the data to measure errors therebetween; and correcting a degree of overlap between the upper layer pattern and the lower layer pattern as necessitated by the degree of error noted in the comparing step to align the two layer patterns.

The results of the overlap between the upper layer pattern and the lower layer pattern can be determined by a scanning electron microscopic image.

The sub-step of comparing the results of the overlap between the upper layer pattern and the lower layer pattern with the data to measure errors therebetween can be carried out with respect to an X-axis and a Y-axis perpendicular to each other.

According to another embodiment, a semiconductor substrate includes an active region provided for defining a plurality of transistors, the active region including a first pattern; and an inactive region including a second patternAn overlay vernier comprising overlay vernier patterns, the second patterns being substantially the same as the first pattern.

### BRIEF DESCRIPTION OF THE DRAWINGS

FIGS. 1 and 2 are views illustrating an overlay vernier according to an embodiment of the present invention;

FIG. 3 is a flow chart illustrating a method for manufacturing a semiconductor device using an overlay vernier according to an embodiment of the present invention.

FIG. 4 is a flow chart illustrating a method for manufacturing a semiconductor device using an overlay vernier according to another embodiment of the present invention.

### DETAILED DESCRIPTION OF THE INVENTION

Specific embodiments of the present invention will now be described in detail with reference to the accompanying drawings. However, these embodiments can be modified and are not to be construed as limiting the scope of the invention.

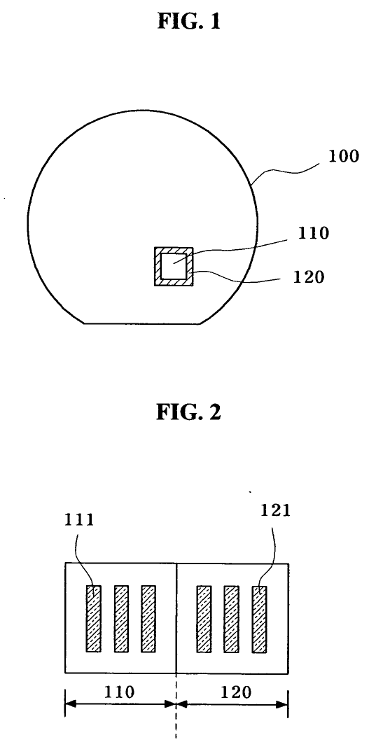

FIGS. 1 and 2 are views illustrating an overlay vernier according to an embodiment of the present invention. Specifically, FIG. 1 is a view showing a real cell and a scribe line within a wafer, and FIG. 2 is a detailed view showing the real cell and the scribe line shown in FIG. 1. The same reference numerals designate the same elements in FIGS. 1 and 2.

Referring to FIGS. 1 and 2, the overlay vernier according to one embodiment of the present invention is disposed in a scribe line 120 of a wafer 100. The scribe line 120 surrounds a real cell 110. The real cell or active region defines an area wherein a plurality of transistors are formed. That is, the real cell 110 is a region where patterns 111 for actual operation of a device are formed, and the scribe line 120 is a region for separating the real cell 110 from adjacent real cells by cutting. Although the patterns 111 within the real cell 110 have a striped shape in FIG. 2, they can be disposed in a layout of a more complex shape. Overlay vernier patterns 121 are disposed within the scribe line 120. The overlay vernier patterns 121 have the same layout as that of the patterns 111 disposed within the real cell 110. Thus problems caused by dissimilar layouts of the real cell patterns and the overlay vernier patterns can be avoided. Misalignment can be prevented between the patterns of the real cell, which may be due to asymmetric lateral slopes produced during lamination and/or the use of a lens with an aberration in a scanner/stepper despite exact overlap of the overlay vernier.

The layout of the overlay vernier patterns 121 is substantially identical to that of the patterns 111 disposed within the real cell 110, but the tone of the overlay vernier patterns 121 may be different from that of the patterns 111. For example, if an upper layer is invisibly covered with a lower layer of the real cell 110, the lower overlay vernier pattern 121 is formed in such a manner as to have a tone different from that of the lower layer pattern 111 of the real cell 1 10. If necessary, the lower overlay vernier pattern 121 may be formed in such a manner as to have the same tone as that of the lower layer pattern 111 of the real cell 110, and instead an upper overlay vernier pattern may be formed in such a manner as to have a tone different from that of the upper layer pattern.

According to another embodiment of the present invention, the overlay vernier is not a separate pattern, but may be a pattern of the real cell 1 10. In this case, an upper layer pattern and a lower layer pattern disposed within the real cell 110 are directly read to determine the degree of overlap between the patterns. The degree of overlap between the upper layer and lower layer patterns can be determined without limitation by scanning the electron microscopy.

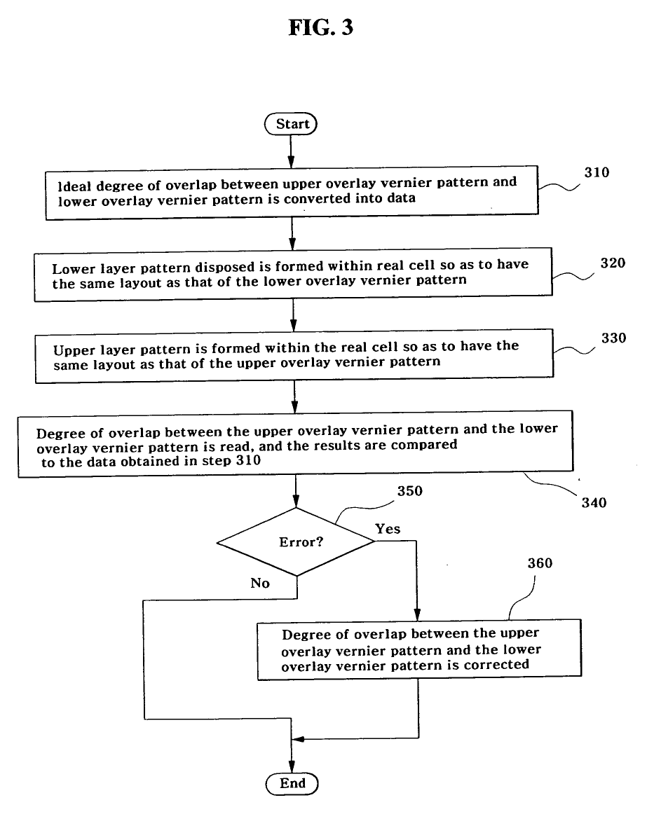

FIG. 3 is a flow chart illustrating the procedure of a method for manufacturing a semiconductor device using an overlay vernier according to an embodiment of the present invention. The overlay vernier of this embodiment comprises overlay vernier patterns formed within a scribe line, which are formed separately from patterns of a real cell.

Referring to FIG. 3, an ideal degree of overlap between an upper overlay vernier pattern as an upper layer and a lower overlay vernier pattern as a lower layer is converted into data (or overlay information) (step 310). The ideal degree of overlap between the upper overlay vernier pattern and the lower overlay vernier pattern can be obtained in the design stage. Thereafter, common exposure, developing, and etching processes are carried out using a first mask so that the lower layer pattern as a lower layer disposed within the real cell has the same layout as that of the lower overlay vernier pattern disposed within a region other than the real cell region, such as a scribe line region (step 320). If the lower overlay vernier pattern is covered with the upper overlay vernier pattern, making the lower overlay vernier pattern difficult to discern, it may be formed in such a manner as to have a tone different from that of the lower layer pattern.

Next, common exposure, developing, and etching processes are carried out using a second mask so that the upper layer pattern as an upper layer disposed within the real cell has the same layout as that of the upper overlay vernier pattern disposed within a region other than the real cell, for example, the scribe line region (step 330). As mentioned above, if the lower overlay vernier pattern is covered with the upper overlay vernier pattern, the upper overlay vernier pattern can be formed instead of the lower overlay vernier pattern using a 180° phase shift mask.

During formation of the upper layer pattern and the upper overlay vernier pattern, the alignment of the upper layer pattern and the lower layer pattern in the real cell can be achieved by aligning the upper overlay vernier pattern and the lower overlay vernier pattern. Since the layout of the lower overlay vernier pattern is substantially identical to that of the lower layer pattern, and the layout of the upper overlay vernier pattern is substantially identical to that of the upper layer pattern, information regarding the overlap between the upper overlay vernier pattern and the lower overlay vernier pattern matches information regarding the overlap between the upper layer pattern and the lower layer pattern.

Next, a degree of overlap between the upper overlay vernier pattern and the lower overlay vernier pattern is read, and the results are compared to the data obtained in step 310 (step 340). The data concerning the degree of overlap between the upper overlay vernier pattern and the lower overlay vernier pattern may be obtained from a scanning electron microscopic (SEM) image. The data obtained in step 310 may also be obtained from a scanning electron microscopic image. The scanning electron microscopic image obtained in step 340 is overlapped with the data obtained in step 310 to determine errors in the directions of the X-axis and the Y-axis. In doing so, the comparison performed in step 340 enables determination of errors (step 350). When no error (or an error less than a predefined error margin) is detected in step 350, the alignment of the upper overlay vernier pattern as the upper layer and the lower overlay vernier pattern as the lower layer is considered to be accurately aligned. On the other hand, when an error (or an error greater than the predefined error margin) is detected in step 350, the degree of overlap between the upper overlay vernier pattern and the lower overlay vernier pattern is corrected so as to compensate for the error (step 360).

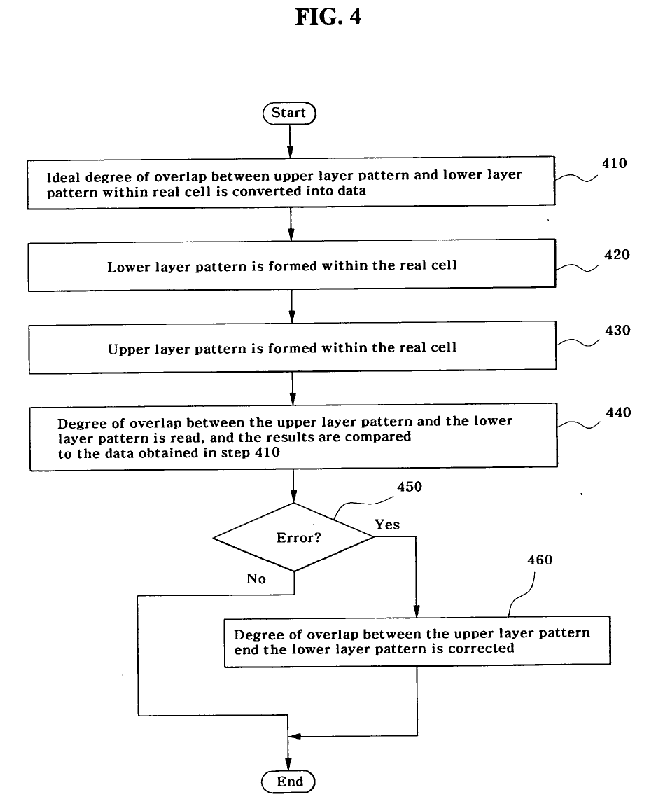

FIG. 4 is a flow chart illustrating the procedure of a method for manufacturing a semiconductor device using an overlay vernier according to another embodiment of the present invention. In this embodiment, the overlay vernier is not formed separately from patterns formed within a real cell. Rather, the patterns formed within a real cell are used as overlay vernier patterns.

Referring to FIG. 4, an ideal degree of overlap between an upper layer pattern as an upper layer and a lower layer pattern as a lower layer in a real cell is converted into data (or overlay information) (step 410). The ideal degree of overlap between the upper layer pattern and the lower layer pattern can be obtained in the design stage. Thereafter, common exposure, developing, and etching processes are carried out using a first mask so that the lower layer pattern is formed within the real cell (step 420). In this embodiment, a separate overlay vernier pattern is formed, unlike the previous embodiment.

Next, common exposure, developing, and etching processes are carried out using a second mask, so that the upper layer pattern, as an upper layer disposed within the real cell, has the same layout as that of the upper overlay vernier pattern disposed within a region other than the real cell, for example, the scribe line region (step 430). The alignment between the upper layer pattern and the lower layer pattern is achieved by direct alignment of the upper layer and lower layer patterns. Accordingly, there exists no difference in the degree of overlap between overlay vernier patterns and the degree of overlap between corresponding patterns formed within a real cell, which have been caused by the use of separate overlay vernier patterns.

Next, the degree of overlap between the upper layer pattern and the lower layer pattern is read, and the results are compared to the data obtained in step 410 (step 440). The data concerning the degree of overlap between the upper layer pattern and the lower layer pattern may be obtained from a scanning electron microscopic (SEM) image. The data obtained in step 410 may also be obtained from a scanning electron microscopic image. The scanning electron microscopic image obtained in step 440 is overlapped with the data obtained in step 410 to determine errors in the directions of the X-axis and Y-axis perpendicular to each other. In doing so, the comparison performed in step 440 enables determination of errors (step 450). When no error is detected in step 450, the upper layer pattern and the lower layer pattern are considered to be accurately aligned. On the other hand, when errors are detected in step 450, the degree of overlap between the upper layer pattern and the lower layer pattern is corrected so as to compensate for the errors (step 460).

As apparent from the above, the overlay vernier and the method for manufacturing a semiconductor device using the overlay vernier according to the present invention provide certain advantages. The pattern layout of a real cell is directly used as the overlay vernier, or an overlay vernier pattern identical to the pattern layout of a real cell is used as the overlay vernier to align an upper layer and a lower layer, consequently, dissimilarity can be prevented between information regarding the alignment of the overlay and information regarding the alignment between patterns of a real cell due to a difference in the layout between the patterns of a real cell and the overlay. As a result, misalignment of the real cell is prevented, leading to an increase in the yield of the device.

Although the present invention has been described herein with reference to its preferred embodiments, these embodiments do not serve to limit the invention, and those skilled in the art will appreciate that various modifications can be made within the technical spirit of the present invention.

What is claimed is:

1. A semiconductor substrate, comprising:
an active region provided for defining a plurality of transistors, the active region including a first pattern; and
an inactive region including a second pattern, the second patterns being substantially the same as the first pattern.

2. The substrate according to claim 1, wherein the second pattern is an overlay vernier pattern, and the inactive region is a scribe region.

3. The substrate according to claim 1, wherein the second pattern has a tone different from that of the first pattern.

4. The substrate according to claim 1, wherein the inactive region is in a scribe region, and the first and second patterns have different tones.

5. A method for manufacturing a semiconductor device, the method comprising:
forming a lower active pattern within an active region of a substrate;
forming a lower overlay vernier pattern in an inactive region of the substrate, the lower active pattern having substantially the same layout as that of the lower overlay vernier pattern within the inactive region of the substrate;
forming an upper active pattern within the active region of the substrate;
forming an upper overlay vernier pattern within the inactive region, the upper active pattern being substantially the same pattern as the upper overlay vernier pattern, the upper overlay vernier pattern overlapping the lower overlay vernier pattern.

6. The method according to claim 5, further comprising defining a first overlap information between the upper overlay vernier pattern and the lower overlay vernier pattern for use as a reference in determining whether or not the upper active pattern and the lower active pattern are aligned properly.

7. The method according to claim 6, wherein the determining whether or the alignment between the upper active pattern and the lower active pattern is proper includes:
determining second overlap information between the upper overlay vernier pattern and the lower overlay vernier pattern;
comparing the first and second overlap informations; and
adjusting an alignment between the upper overlay vernier pattern and the lower overlay vernier pattern according to a result obtain from the comparing step.

8. The method according to claim 7, wherein the second overlap information between the upper overlay vernier pattern and the lower overlay vernier pattern is determined by a scanning electron microscopic image.

9. The method according to claim 7, wherein the comparing step is performed with respect to first and second directions that are perpendicular to each other.

10. The method according to claim 5, wherein the inactive region includes a scribe line.

11. The method according to claim 5, wherein the lower overlay vernier pattern is configured to have a different tone from that of the lower active pattern.

12. A method for manufacturing a semiconductor device, the method comprising:
forming a lower pattern within an active cell region of a wafer;
forming an upper pattern within the active cell region so that the upper pattern directly overlaps the lower pattern to align the two patterns;
obtaining an overlap information on the upper pattern and the lower pattern;
comparing the overlap information between the upper pattern and the lower pattern with an ideal degree of overlap between the upper and lower patterns to measure an error margin between the overlap information and the ideal degree of overlap; and
adjusting the overlap between the upper pattern and the lower pattern according to the errors obtained in the comparing step to align the upper and lower patterns.

13. The method according to claim 12, wherein the overlap information between the upper pattern and the lower pattern is determined by a scanning electron microscopic image.

14. The method according to claim 12, wherein the comparing step is performed with respect to first and second directions that are perpendicular to each other.
